(19) United States
(12) Patent Application Publication
(10) Pub. No.: US 2002/0003304 A1
(43) Pub. Date: Jan. 10, 2002

(54) Semiconductor device having multilevel interconnection

(75) Inventors: Noriaki Matsunaga, Chigasaki-shi (JP); Hisashi Kaneko, Fujisawa-shi (JP); Soichi Nadahara, Yokohama-shi (JP)

Correspondence Address: Finnegan, Henderson, Farabow, Garrett & Dunner, L.L.P., 1300 I Street, N.W., Washington, DC, 20005-3315, US

(73) Assignee: Kabushiki Kaisha Toshiba

(21) Appl. No.: 09/899,233

(22) Filed: Jul. 6, 2001

(30) Foreign Application Priority Data
Jul. 7, 2000 (JP) 2000-207330

(51) Int. Cl. H01L 23/053; H01L 23/12; H01L 23/48

(52) U.S. Cl. 257/758; 257/701; 257/700

(57) ABSTRACT

The semiconductor device has the first module having the first interconnection line, the second module having the second interconnection line which is shorter than the first interconnection line, the second module is formed separately from the first module, the second module is attached to the first module in a laminating direction of the first and second interconnection lines, and the second interconnection line and the first interconnection line are electrically connected to each other, and a ground line provided within the first module and paired with the first interconnection line.

### CROSS-REFERENCE TO RELATED APPLICATIONS

This application is based upon and claims the benefit of priority from the prior Japanese Patent Application No. 2000-207330, filed Jul. 7, 2000, the entire contents of which are incorporated herein by reference.

### BACKGROUND OF THE INVENTION

1. Field of the Invention

The present invention relates to a semiconductor device having a multilevel interconnection.

2. Description of the Related Art

Recently, a transmission line is formed in a multilevel interconnection of a semiconductor device in order to transmit a high-speed signal at a high efficiency. In the most popular semiconductor device, a ground line is formed to make a pair with a signal wiring line as will be described below.

That is, as can be seen in FIG. 9, a plurality of high-speed long-distance interconnection lines 21 and a plurality of low-speed short-distance interconnection lines 22 are mixedly formed in one layer. Above these interconnection lines 21 and 22, a first interlayer insulating film 23 is formed. A plurality of ground lines 24 are formed on the first interlayer insulating film 23, and a second interlayer insulating film 25 is formed on the ground lines 24.

Similarly, a plurality of high-speed long-distance interconnecting lines 26 and a plurality of low-speed short-distance interconnection lines 27 are mixedly formed on second interlayer insulating film 25. Above these interconnection lines 26 and 27, a third interlayer insulating film 28 is formed. A plurality of ground lines 29 are formed on the third interlayer insulating film 28, and a fourth interlayer insulating film 29 is formed on the ground lines 29.

With the ground lines 24 and 29 provided as above, noise created between the lines 26 and 27 is decreased, and signals are transmitted at a high speed.

However, in the conventional semiconductor device, the line materials and line formation process are limited to those which have been conventionally employed. Therefore, in the case where ground lines 24 and 29 having a relatively high coverage rate are formed, a problem such as the ground lines 24 and 29 being peeled off due to an uneven stress may easily occur. Or in the case where such a large-area wiring pattern as of ground lines 24 and 29 is formed by a CMP (chemical mechanical polish) method using Cu as the line material, it is difficult to suppress dishing and therefore, a part of the wiring pattern is sometimes lost.

As described above, the conventional semiconductor device entails the drawback that it is very difficult to achieve a high-speed signal transmission and to relax the limitation on the materials and process.

### BRIEF SUMMARY OF THE INVENTION

According to the first aspect of the present invention, there is provided a semiconductor device comprising: a first module having a first interconnection line; a second module having a second interconnection line which is shorter than the first interconnection line, the second module being formed separately from the first module, the second module being attached to the first module in a laminating direction of the first and second interconnection lines, and the second interconnection line and the first interconnection line are electrically connected to each other; and a ground line provided within the first module and paired with the first interconnection line.

According to the second aspect of the present invention, there is provided a semiconductor device according to the first aspect, wherein the first interconnection line is arranged between the ground line and the second interconnection line.

According to the third aspect of the present invention, there is provided a semiconductor device according to the first aspect, further comprising: a first pad provided in the first module and connected to the first interconnection line; a second pad provided in the second module and connected to the second interconnection line, the second pad being formed to face the first pad; and an insulating member provided between the first and second modules, the first and second interconnection lines being electrically connected to each other by a capacitance coupling consisting of the insulating member, and the first and second pads.

According to the fourth aspect of the present invention, there is provided a semiconductor device according to the second aspect, wherein a part of the ground line serves as a pad electrode.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently embodiments of the invention, and together with the general description given above and the detailed description of the embodiments given below, serve to explain the principles of the invention.

FIG. 1 is a cross sectional view showing a semiconductor device according to the first embodiment of the present invention;

FIGS. 2A, 2B, 2C and 2D are cross sectional views each showing a different version of the semiconductor device according to the first embodiment of the present invention each;

FIG. 3 is a cross sectional view showing a semiconductor device according to the second embodiment of the present invention;

FIG. 4 is a cross sectional view showing a semiconductor device according to the third embodiment of the present invention;

FIG. 5 is a partially enlarged view of the semiconductor device according to the third embodiment shown in FIG. 4;

FIG. 6 is a circuit diagram of the semiconductor device according to the third embodiment shown in FIG. 5;

FIG. 7 is a diagram showing a relationship of the maximum thickness of the insulating film with regard to the frequency and electrode area;

FIG. 8 is a cross sectional view showing a semiconductor device according to the fourth embodiment of the present invention; and

FIG. 9 is a cross sectional view showing a semiconductor device according to the conventional technique.

### DETAILED DESCRIPTION OF THE INVENTION

Embodiments of the present invention will now be described with reference to accompanying drawings. Throughout the descriptions of the embodiments and the drawings, the like structural elements will be designated by the same reference numerals.

[First Embodiment]

The characteristic feature of the first embodiment is that the first module having a long-distance interconnection line and a ground line and the second module having a short-distance interconnection line are formed separately, and then these modules are adhered together. It should be noted that the first embodiment is the basic structure of the present invention.

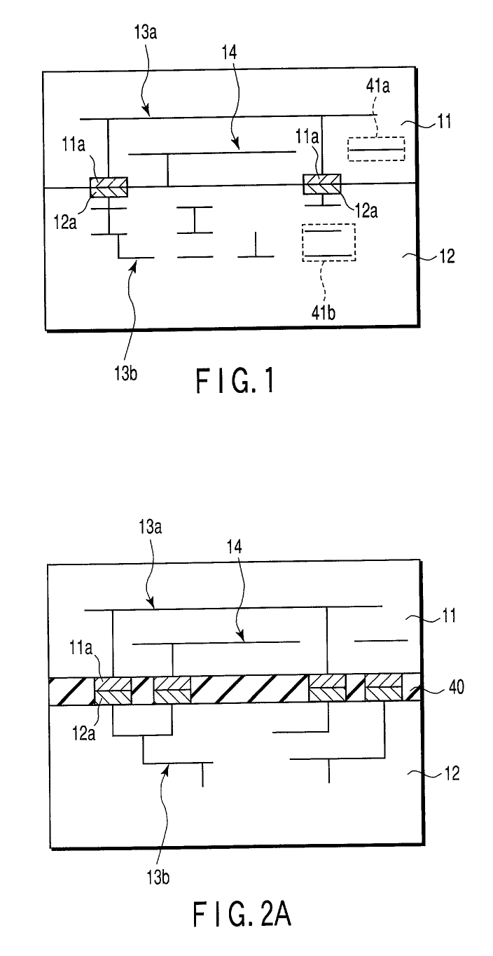

FIG. 1 is a cross section view of a semiconductor device according to the first embodiment of the present invention. As shown in FIG. 1, various wires are divided into long-distance interconnection lines 13a and short-distance interconnection lines 13b. Then, a first module 11 is formed and it includes the long-distance interconnection lines 13a, pads 11a connected to the long-distance interconnection lines 13a and ground lines 14 each of which makes a pair with a respective one of the long-distance interconnection lines 13a. On the other hand, separately from the first module 11, a second module 12 is formed and it includes the short-distance interconnection lines 13b and pads 12a connected to the short-distance interconnection lines 13b is formed. After that, the first and second modules 11 and 12 are adhered together in the laminating direction of the interconnection lines 13a and 13b, and thus the pads 11a and 12a are electrically connected to each other. Thus, the first and second modules 11 and 12 are integrated as one unit and a chip is formed.

Further, it is structurally allowable that circuits 41a and 41b made of active or passive elements such as MOSFETs may be present in the first and second modules 11 and 12. Such circuits 41a and 41b in the two modules 11 and 12 function as LSI circuits, and signals are processed with use of these circuits 41a and 41b.

It should be noted that short-distance interconnection lines 13 may be mixed in the first module 11.

In the first embodiment, the separation of the long-distance interconnection lines 13a and the short-distance interconnection lines 13 can be carried out in the following manner. For example, where the frequency used is represented by f_{c}, the resistance of lines separated per unit length is represented by r, the capacitance of lines separated per unit length is represented by c, and the length of an interconnection line for reference is represented by L_{c}, the relationship expressed by the following equation (1) can be induced.

f_{c}=½πrcL_{c}² (1)

Therefore, the length L_{c} is expressed by the following equation (2), according to which, it is understood that the length L_{c} varies from one frequency f_{c} used to another.

L_{c}=√½πrcf_{c} (2)

From the equation (2), in the case where the length of the interconnection line to be separated is L, and if L_{c}<L, the line is regarded as a long-distance interconnection line 13a, whereas if L<L_{c}, the line is regarded as a short-distance interconnection line 13b.

For example, a long-distance interconnection line 13a has a length of several hundred μm or more, and is used for interconnection between a bit line and word line in a memory or interconnection between a memory and the CPU in an LSI circuit. On the other hand, a short-distance interconnection line 13b has a length of several to several hundred μm, and is used for interconnection between adjacent transistors.

According to the first embodiment, the first module 11 and the second module 12 are separately formed. In this manner, the material for the interconnection lines or for the interlayer insulating films can be changed in accordance with the performance required for each of the modules 11 and 12, and further an optimal process for the object of each of the modules 11 and 12 can be selected.

More specifically, the long-distance interconnection lines 13a and the ground lines 14 in the first module 11 are formed of, for example, Al films, whereas the short-distance interconnection lines 13b in the second module 11 are formed of, for example, Cu films. With this structure, the long-distance interconnection lines 13 and the ground lines 14, which are made of the Al films, can be patterned by RIE (reactive ion etching), and therefore it is no longer necessary to pattern it using CMP (chemical mechanical polish). Therefore, the problem of dishing, which entails to the case where CMP is employed, does not occur.

Further, the most appropriate interconnection material having a low stress can be selected for each of the modules 11 and 12, and therefore the problem of peeling-off of films, which occurs due to stress, can be suppressed.

Furthermore, in the first module 11, long-distance interconnection lines 13a which require high-speed processes are provided, and therefore it is important to decrease the capacitance of the interconnection line. Here, as an interlayer insulating film in the first module 11, it suffices if a low dielectric constant film having a specific dielectric constant of about 4.0 or less is used. In this manner, the capacitance can be lowered in the first module 11. On the other hand, an element which generates heat is formed in the second module 12, and therefore as the interlayer insulating film, a material having a high heat radiating property is required. Therefore, as the interlayer insulating film of the second module 12, it suffices if a film having a heat radiating property higher than that of a low dielectric film and having a high strength (that is, for example, a silicon oxide film) is used. In this manner, in the second module 12, the heat radiating property can be improved while fully protecting the element.

As described above, the limitations of the material properties and process can be relaxed, and therefore the degree of freedom in terms of the material type as well as the process type.

Moreover, the structure of the first embodiment is divided into the first module 11 including the long-distance interconnection lines 13a and the second module 12 including the short-distance interconnection line 13b. In this structure, it suffices if the ground lines 14 are formed only in the first module 11. With this structure, it is possible to suppress the number of wiring layers to the minimum necessary limit, and therefore the number of steps for making multilevel interconnection can be reduced as compared to the case where the long-distance interconnection lines 13a and the short-distance interconnection lines 13b are mixedly present. Therefore, the production cost can be reduced.

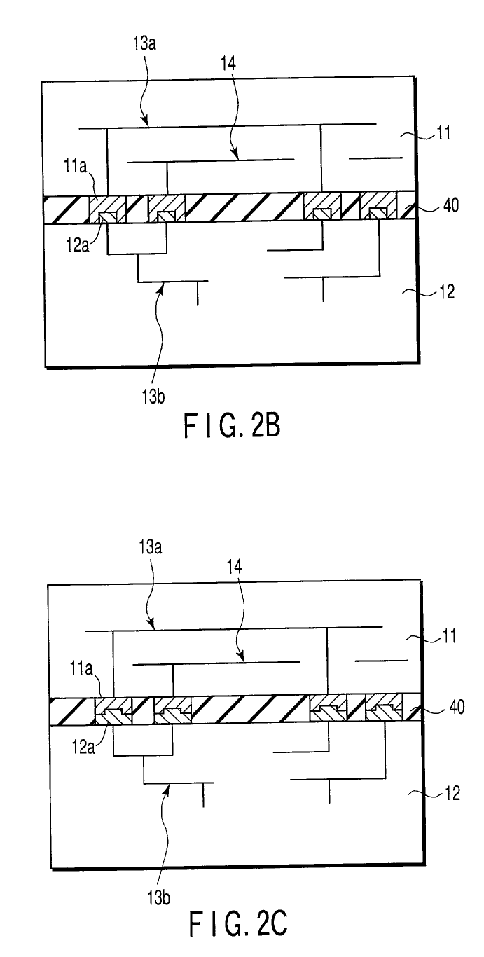

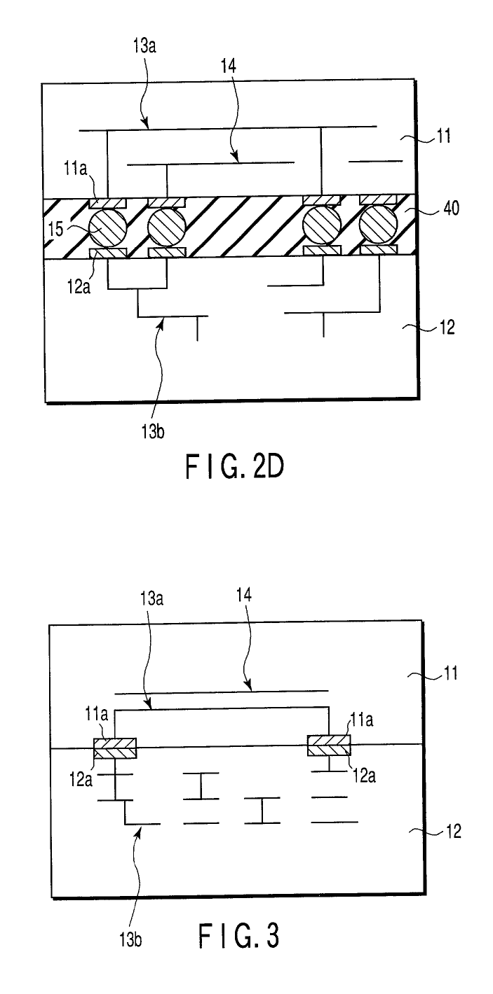

It should be noted here that the connection between the first module 11 and the second module 12 is not limited to the type shown in FIG. 1, but may be of those shown in FIGS. 2A to 2D.

For example, as shown in FIG. 2A, the modules 11 and 12 may be connected together in such a manner that pads 11a and 12a are provided such as to project from the modules 11 and 12 respectively, and a gap between the modules 11 and 12 is filled with an insulating member 40 such as a resin. In this case, a recess portion may be made in either one of the pads 11a and 12b, and a projecting portion is made in the other one of these pads as can be seen in FIGS. 2A and 2C, so that the pads 11a and 12a can be easily engaged with each other.

Alternatively, as shown in FIG. 2D, pads 11a and 12a are provided on outer sides of the modules 11 and 12, respectively, and a conductive connector element 15 such as a bump is provided between the pads 11a and 12b. Further, a gap between the modules 11 and 12 is filled with an insulating member 40 and thus the modules 11 and 12 are connected together. Here, as the conductive connecting element 15, an anisotropic conductive sheet may be used.

With the above-described interconnections as well, the same effect as that of the first embodiment can be obtained, with a further effect of easier interconnection between the modules 11 and 12.

[Second Embodiment]

The characteristic feature of the second embodiment is that a long-distance interconnection line is formed and arranged between a ground line and a short-distance interconnection line. The parts of the structure of the second embodiment which are different from those of the first embodiment will now be described in detail.

FIG. 3 is a diagram showing a cross section of a semiconductor device according to the second embodiment of the present invention. As can be seen in FIG. 3, the feature different from that of the first embodiment is that a long-distance interconnection line 13a a is situated between a ground line 14 and a short-distance interconnection line 13b. In other words, the ground line 14 is located on the other side of the short-distance interconnection line 13b with regard to the long-distance interconnection line 13a which makes a pair together with the ground line 14.

With the second embodiment, it is possible to obtain the same effect as that of the first embodiment.

Further, as mentioned above, the ground line 14 in the first module 11 is located on the other side of the short-distance interconnection line 13b with regard to the long-distance interconnection line 13a which makes a pair together with the ground line 14. With this structure, there is no ground line 14 present between the modules 11 and 12 in order to transmit signals from the second module 12 to the first module 11. Therefore, the short-distance interconnection line 13b can be connected directly to the long-distance interconnection line 13a via the pads 11a and 12a, thereby making it possible to increase the speed of signal transmission between the modules 11 and 12.

[Third Embodiment]

The characteristic feature of the third embodiment is that an insulating film is provided between the first and second modules, and pads in the modules are capacity-coupled via the insulating film. The parts of the structure of the second embodiment which are different from those of the first embodiment will now be described in detail.

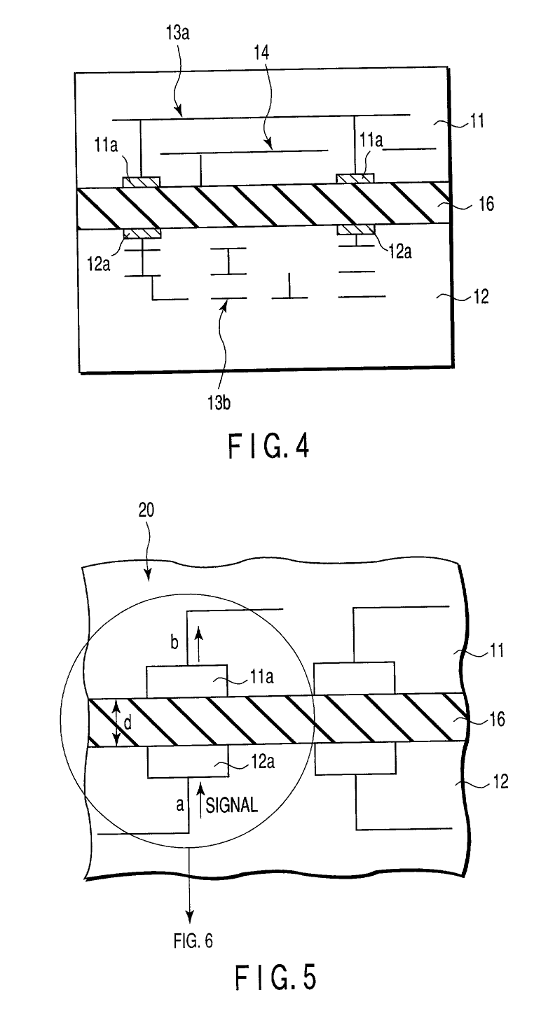

FIG. 4 is a diagram showing a cross section of a semiconductor device according to the third embodiment of the present invention. As can be seen in FIG. 4, the feature different from that of the first embodiment is that an insulating film 16 is provided between the first and second modules 11 and 12, and pads 11a and 12a within these modules 11 and 12 are capacity-coupled via the insulating film 16.

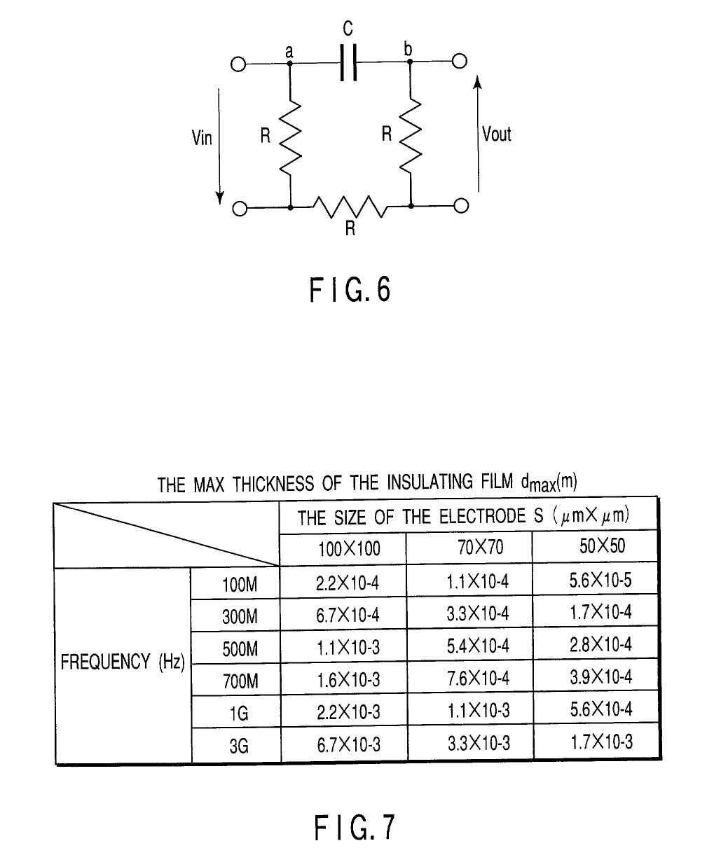

FIG. 5 is a partially enlarged view of the semiconductor device according to the third embodiment shown in FIG. 4. FIG. 6 is a circuit diagram of the semiconductor device shown in FIG. 5. As can be seen in FIGS. 5 and 6, with the insulating film 16 provided between the first and second modules 11 and 12, a capacitor 20 consisting of the pads 11a and 12a and the insulating film 16 is formed. Thus, a signal is transmitted, for example, from a to b by the capacity coupling between the pads 11a and 12a via the insulating film 16. In this manner, with use of a serial capacitor 20, interconnection lines 13a and 13b in the modules 11 and 12 are connected together, and thus signals are transmitted between the modules 11 and 12.

FIG. 7 is a diagram showing a relationship of the maximum thickness of the insulating film with regard to the frequency and electrode area. In the case where the thickness of the insulating film 16 is represented by d, the frequency employed is represented by f, the area of the electrode (pad 11a or 12a) is represented by S, and the resistance of the insulating film 16 is represented by R, the following equation (3) is obtained.

d=2πfεSR (3)

From this equation (3), the maximum thickness dₘₐₓ of the insulating film 16, with which signals can be transmitted, can be calculated for variables such as the frequency f employed and the area S of the electrode. As can be understood from this equation, when the thickness of the insulating film 16 is set no more than the maximum thickness dₘₐₓ indicated in FIG. 7, signals can be transmitted at high efficiency.

With the third embodiment described above, it is possible to obtain an effect similar to that of the first embodiment.

Further, with the insulating film 16 provided between the first and second modules 11 and 12, a capacitor 20 is formed. The signal transmission between the modules 11 and 12 can be carried out with use of the capacitor 20, and therefore it is no longer necessary to provide a conductive connector element. As a result, the processing step for forming a connection element can be deleted.

It should be further noted that the structure of the second embodiment may be applied to the third embodiment. In this case, a similar effect to that of the second embodiment can be obtained.

[Fourth Embodiment]

The characteristic feature of the fourth embodiment is that a ground pad is formed at the same time and at the same surface level as those of the ground line.

The fourth embodiment which will now be discussed is achieved by applying the above-described structure to the third embodiment, however it is not limited to such a structure. Only the different structural parts from those of the second or third embodiment will be discussed here in details.

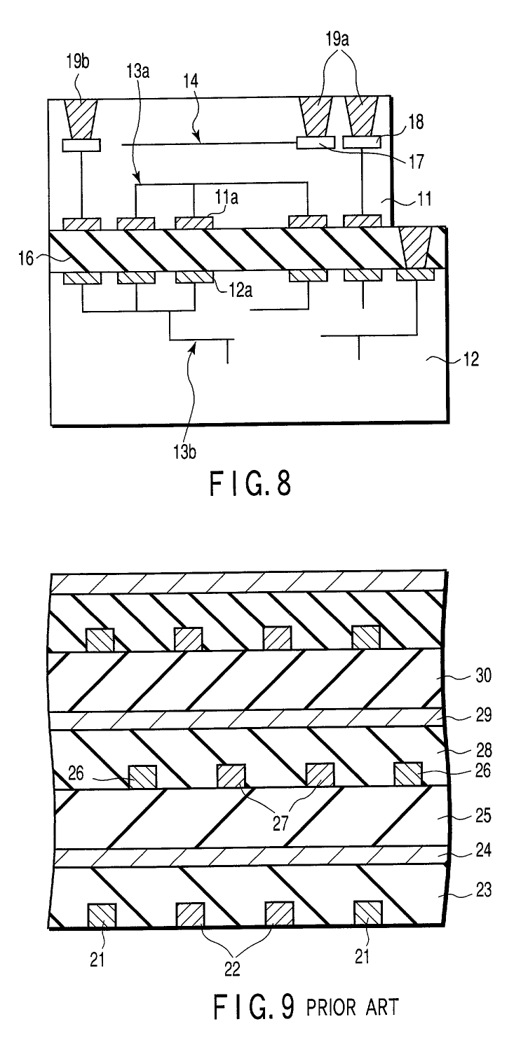

FIG. 8 is a cross sectional diagram of a semiconductor embodiment according to the fourth embodiment of the present invention. As can be seen in FIG. 8, a ground line 14 in the first module 11 is provided in a region on an opposite side of the short-distance interconnection line 13b with respect to the long-distance interconnection line 13a which makes a pair with the ground line 14. The different structural aspect from that of the third embodiment is that a ground pad 17 is formed at the same surface level as that of the ground line 14 and at the same time as the formation of the ground line 14. With this structure, a part of the ground line 14 functions as the ground pad 17.

Further, a pad electrode 18 connected to some other element (not shown) may be formed at a region in the same level as that of the ground line 14. Alternatively, a pad window 19a is formed above the ground pad 17 and the pad electrode 19, and further a signal retrieval window 19b for retrieving signals is formed independently from the pad window 19a.

With the fourth embodiment described above, it is possible to obtain an effect similar to that of the second or third embodiment.

Further, the ground line 14 in the first module 11 is provided in a region on an opposite side of the short-distance interconnection line 13b with respect to the long-distance interconnection line 13a which makes a pair with the ground line 14. With this structure, the ground pad 17 and the pad electrode 18 which must be provided on an outer side to the integrated modules 11 and 12 can be formed in a region at the same level as that of the ground line 14 and at the same time as the formation thereof. Therefore, the number of steps for forming the ground pad 17 and the pad electrode 18 can be reduced, and therefore the ground pad 17 and the pad electrode 18 can be easily formed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a first module having a first interconnection line;
a second module having a second interconnection line which is shorter than the first interconnection line, said second module being formed separately from said first module, said second module being attached to the first module in a laminating direction of the first and second interconnection lines, and said second interconnection line and said first interconnection line are electrically connected to each other; and
a ground line provided within said first module and paired with said first interconnection line.

2. A semiconductor device according to claim 1, wherein said first interconnection line is arranged between said ground line and said second interconnection line.

3. A semiconductor device according to claim 1, further comprising:
a first pad provided in said first module and connected to said first interconnection line; and
a second pad provided in said second module and connected to said second interconnection line, said second pad being formed to face said first pad, said first and second interconnection lines being electrically connected to each other via said first and second pads.

4. A semiconductor device according to claim 2, further comprising:
a first pad provided in said first module and connected to said first interconnection line; and
a second pad provided in said second module and connected to said second interconnection line, said second pad being formed to face said first pad, said first and second interconnection lines being electrically connected to each other via said first and second pads.

5. A semiconductor device according to claim 1, further comprising:
a first pad provided in said first module and connected to said first interconnection line;
a second pad provided in said second module and connected to said second interconnection line, said second pad being formed to face said first pad; and
a conductive connection element formed between said first and second modules, said first and second interconnection lines being electrically connected to each other via said connection element and said first and second pads.

6. A semiconductor device according to claim 2, further comprising:
a first pad provided in said first module and connected to said first interconnection line;
a second pad provided in said second module and connected to said second interconnection line, said second pad being formed to face said first pad; and
a conductive connection element formed between said first and second modules, said first and second interconnection lines being electrically connected to each other via said connection element and said first and second pads.

7. A semiconductor device according to claim 5, wherein said connection element is one of a bump and an anisotropic conductive sheet.

8. A semiconductor device according to claim 6, wherein said connection element is one of a bump and an anisotropic conductive sheet.

9. A semiconductor device according to claim 1, further comprising:
a first pad provided in said first module and connected to said first interconnection line;
a second pad provided in said second module and connected to said second interconnection line, said second pad being formed to face said first pad; and
an insulating member provided between said first and second modules, said first and second interconnection lines being electrically connected to each other by a capacitance coupling of said insulating member, and said first and second pads.

10. A semiconductor device according to claim 2, further comprising:
a first pad provided in said first module and connected to said first interconnection line;
a second pad provided in said second module and connected to said second interconnection line, said second pad being formed to face said first pad; and
an insulating member provided between said first and second modules, said first and second interconnection lines being electrically connected to each other by a capacitance coupling of said insulating member, and said first and second pads.

11. A semiconductor device according to claim 9, wherein a relationship of d≦2πfεSR is satisfied where a thickness of said insulating member is represented by d, a frequency employed is represented by f, an area of said first and second pads is represented by S, and a resistance of said insulating member is represented by R.

12. A semiconductor device according to claim 10, wherein a relationship of d≦2πfεSR is satisfied where a thickness of said insulating member is represented by d, a frequency employed is represented by f, an area of said first and second pads is represented by S, and a resistance of said insulating member is represented by R.

13. A semiconductor device according to claim 1, wherein relationships:
L₂<√½πr₂c₂f_{c}, √½πr₁c₁f_{c}<L₁ is satisfied, where a frequency used is represented by f_{c}, a resistance of said first interconnection line is represented by r₁, a resistance of said second interconnection line is represented by r₂, a capacitance of said first interconnection line is represented by c₁, a capacitance of said second interconnection line is represented by c₂, a length of said first interconnection line is represented by L₁, and a length of said first interconnection line is represented by L₂.

14. A semiconductor device according to claim 2, wherein relationships:
L₂<√½πr₂c₂f_{c}, √½πr₁c₁f_{c}<L₁ is satisfied, where a frequency used is represented by f_{c}, a resistance of said first interconnection line is represented by r₁, a resistance of said second interconnection line is represented by r₂, a capacitance of said first interconnection line is represented by c₁, a capacitance of said second interconnection line is represented by c₂, a length of said first interconnection line is represented by L₁, and a length of said first interconnection line is represented by L₂.

15. A semiconductor device according to claim 1, further comprising:
a first circuit provided in said first module and connected to said first interconnection line; and
a second circuit provided in said second module and connected to said second interconnection line, processing of a signal being carried out using said first and second circuits.

16. A semiconductor device according to claim 2, further comprising:
a first circuit provided in said first module and connected to said first interconnection line; and
a second circuit provided in said second module and connected to said second interconnection line, processing of a signal being carried out using said first and second circuits.

17. A semiconductor device according to claim 1, wherein said second interconnection line is provided in said first module.

18. A semiconductor device according to claim 2, wherein said second interconnection line is provided in said first module.

19. A semiconductor device according to claim 2, wherein a part of said ground line functions as a pad electrode.

20. A semiconductor device according to claim 3, wherein said first and second pads are projected from said first and second modules.

21. A semiconductor device according to claim 3, wherein a projection portion is provided for one of said first and second pads, and a recess portion is provided for an other one of said first and second pads, said projection portion and said recess portion engaging with each other.

22. A semiconductor device according to claim 1, wherein an insulating film formed between said first interconnection layers is a low dielectric film and an insulating film formed between said second interconnection layers is a silicon oxide film.
